(19) United States
(12) Patent Application Publication
(10) Pub. No.: US 2024/0026542 A1
(43) Pub. Date: Jan. 25, 2024

(54) STEAM DISTRIBUTION DEVICE AND METHOD RELATING TO SAME

(71) Applicant: VON ARDENNE Asset GmbH & Co. KG, Dresden (DE)

(72) Inventors: Bruno HEIMKE, Dresden (DE); Rolf RANK, Dresden (DE); Christian KARN, Dresden (DE)

(21) Appl. No.: 18/355,461

(22) Filed: Jul. 20, 2023

(30) Foreign Application Priority Data
Jul. 22, 2022 (DE) 10 2022 118 437.4

(51) Int. Cl. C23C 16/52; C23C 16/455

(52) U.S. Cl. CPC C23C 16/52; C23C 16/45559; C23C 16/45563

(57) ABSTRACT

Disclosed herein are devices, systems, and methods for gas distribution in a coating process. The system may determine information representing a spatial distribution of a material vapor flow emitted from a plurality of emission nozzles. The system may control a regulator configured to affect, based on the information, a gas flow superposed on the material vapor flower. In this manner, it may be easier to counteract disturbances in the spatial distribution with which the material vapor flow exits from the plurality of emission nozzles, disturbances due to, for example, variations in the characteristics of the emission nozzles, flow-related variations in the tube, finite tube length, and the like.

### CROSS-REFERENCE TO RELATED APPLICATION(S)

This application claims priority to German Patent Application No. 10 2022 118 437.4 filed on Jul. 22, 2022, the contents of which are incorporated fully herein by reference.

### TECHNICAL FIELD

The disclosure relates generally to steam distribution devices and methods, and in particular, to steam distribution devices for use in coating processes for coating substrates such as glass substrates.

### BACKGROUND

In general, a substrate, such as a glass substrate, may be coated so that the chemical and/or physical properties of the substrate may be changed. A coating process may be carried out, for example, by thermally evaporating a material to be evaporated (also referred to as evaporation material or coating material), and depositing the vapor thus formed on the substrate. For this purpose, an evaporator may be used, usually including a plurality of nozzles that emit the vapor in the direction of the substrate. A commonly-used configuration is the so-called linear evaporator, in which the material to be evaporated is fed into a tube including a series of emission nozzles from which the material to be evaporated exits as a material vapor flow.

The spatial distribution with which the material vapor flow exits from such an array of emission nozzles (also referred to as an array of nozzles) may be subject to disturbances, for example, due to variations in the characteristics of the emission nozzles, flow-related variations in the tube, finite tube length, and the like. This may result in non-uniform coating (for example, layer inhomogeneity), especially at the edge of the coating (in the case of, for example, varying distance to the substrate, different substrate thicknesses, change of evaporation material). These disturbances may conventionally only be countered by replacing the emission nozzle(s) in question, but this may only be done if the coating process is interrupted. Furthermore, it may be necessary to repeat such a nozzle replacement, for example when the coating material is changed or a different setting is changed.

### BRIEF DESCRIPTION OF THE DRAWINGS

In the following description, various exemplary aspects of the disclosure are described with reference to the following drawings, in which:

FIGS. 1-3 each show a steam distribution device according to various embodiments of different schematic views;

FIG. 4 shows a process according to various embodiments in a schematic flow chart;

FIGS. 5-8 show, respectively, a steam distribution device according to various embodiments of various schematic views; and

FIGS. 9-10 each show a process according to different embodiments in a schematic flowchart.

### DESCRIPTION

The following detailed description refers to the accompanying drawings that show, by way of illustration, exemplary details, and features.

The word “exemplary” is used herein to mean “serving as an example, instance, or illustration.” Any aspect or design described herein as “exemplary” is not necessarily to be construed as preferred or advantageous over other aspects or designs.

Throughout the drawings, it should be noted that like reference numbers are used to depict the same or similar elements, features, and structures, unless otherwise noted.

In the following detailed description, reference is made to the accompanying drawings which form part thereof and in which are shown, for illustrative purposes, specific embodiments in which the invention may be practiced. In this regard, directional terminology such as “top”, “bottom”, “front”, “rear”, “forward”, “rearward”, etc. is used with reference to the orientation of the figure(s) described. Since components of embodiments may be positioned in a number of different orientations, the directional terminology is for illustrative purposes and is not limiting in any way. It is understood that other embodiments may be used and structural or logical changes may be made without departing from the scope of protection of the present invention. It is understood that the features of the various exemplary embodiments described herein may be combined, unless otherwise specifically indicated. Therefore, the following detailed description is not to be construed in a limiting sense, and the scope of protection of the present invention is defined by the appended claims.

In the context of this description, the terms “connected”, “attached” as well as “coupled” are used to describe both a direct and an indirect connection (e.g. ohmic and/or electrically conductive, e.g. an electrically conductive connection), a direct or indirect connection as well as a direct or indirect coupling. In the figures, identical or similar elements are given identical reference signs where appropriate.

The term “coupled” or “coupling” may be understood in the sense of a connection and/or interaction (e.g. direct or indirect) (e.g. mechanical, hydrostatic, thermal, and/or electrical). For example, a plurality of elements may be coupled together along an interaction chain along which the interaction may be exchanged, e.g., a fluid (also referred to as fluidically coupled, fluidly connected, etc.). For example, two coupled elements may exchange an interaction with each other, e.g., a mechanical, hydrostatic, thermal, and/or electrical interaction. A coupling of a plurality of vacuum components (e.g. valves, pumps, chambers, etc.) to each other may include being fluidly coupled to each other. “Coupled” may be understood in the sense of a mechanical (e.g. physical, or physical) coupling, e.g., by means of direct physical contact. A coupling may be configured to transmit a mechanical interaction (e.g. force, torque, etc.).

The actual state of an entity (e.g. a device, a system, or a process) may be understood as the state of the entity that is actually present or may be sensed. The desired state of the entity may be understood as the target state, i.e. according to a reference, requirement, or specification. Controlling may be understood as an intended influencing of the current state (also referred to as the actual state) of the entity. In this context, the instantaneous state may be changed according to the specification/requirement (also referred to as desired state), e.g. by changing one or more than one operating parameter (also referred to as a manipulated variable) of the entity, e.g. by means of a regulator. Regulating may be understood as controlling, where additionally a change of state is counteracted by disturbances. For this purpose, the actual state is compared with the desired state and the entity is influenced, e.g. by means of a regulator, in such a way that the deviation of the actual state from the desired state is minimized. Thus, in contrast to pure forward control, closed-loop control implements a continuous influence of the output variable on the input variable, which is impacted by the so-called closed-loop control (also referred to as feedback). In other words, it may be understood herein that a closed-loop control may be used alternatively or in addition to a pure forward control, and the terms controlling and regulating may be used interchangeably.

The state of a controllable device (e.g. a steam distribution device) or a controllable process (e.g. coating process) may be specified as a point (also referred to as operating point) in a chamber (also referred to as state space) spanned by the variable parameters (also referred to as operating parameters) of the device or process. The state of the device or operation is thus a function of the respective value of one or more than one operating parameter, which thus represents the state of the device or operation. The actual state may be determined based on a measurement (e.g. by means of a measuring device, e.g. a sensor thereof) of one or more than one operating parameter (also referred to as a controlled variable).

A sensor (also referred to as a detector) may be understood as a converter configured to capture as a measurand (e.g. qualitative or quantitative) a property of the sensor's environment (e.g. a physical property, a chemical property, and/or a material property) corresponding to the type of sensor. The measurand is the physical quantity to which the sensor's measurement applies. Depending on the complexity of the environment to be measured, the sensor may be configured to distinguish between only two states of the measurand (also referred to as a measurement switch), to be able to distinguish between more than two states of the measurand, or to capture the measurand quantitatively. An example of a quantitatively captured measurand is, for example, a pressure whose actual state may be captured as a value by means of the sensor.

A sensor may be part of a measuring chain, which includes a corresponding infrastructure (e.g. processor, storage medium and/or bus system and the like). The measurement chain may be configured to control the corresponding sensor (e.g. gas sensor, pressure sensor and/or rate sensor) to process its captured measured variable as an input variable and, based on this, to provide an electrical signal as an output variable representing the input variable. The measurement chain may be implemented by means of a control device, for example.

The term “control device” may be understood as any type of logic-implementing entity that may, for example, includes circuitry and/or a processor that may, for example, execute software stored in a storage medium, in firmware, or in a combination thereof, and issue instructions based thereon. For example, the control device may be configured using code segments (e.g. software). For example, the control device may include or be formed from a programmable logic controller (PLC).

According to various embodiments, a data storage device (commonly referred to as a storage medium) may be a non-volatile data storage device. For example, the data storage may include or be formed from a hard disk and/or at least one semiconductor memory (such as read-only memory, random access memory, and/or flash memory). The read-only memory may be, for example, an erasable programmable read-only memory (also referred to as an EPROM). The random access memory may be a non-volatile random access memory (also referred to as NVRAM). For example, the data memory may store one or more than one of the following: the code segments representing the method, one or more than one target state, one or more than one time dependency of the target state, one or more than one parameter representing geometry, and the like.

The term “processor” may be understood as any type of entity that allows processing of data or signals. For example, the data or signals may be handled according to at least one (i.e., one or more than one) specific function performed by the processor. A processor may include or be formed from an analogue circuit, a digital circuit, a mixed signal circuit, a logic circuit, a microprocessor, a central processing unit (CPU), a graphics processing unit (GPU), a digital signal processor (DSP), a programmable gate array (FPGA), an integrated circuit, or any combination thereof. Any other type of implementation of the respective functions, described in more detail below, may also be understood as a processor or logic circuit, for example also virtual processors (or a virtual machine) or a plurality of decentralized processors, for example interconnected by means of a network, spatially distributed as desired, and/or having an as-desired share in the implementation of the respective functions (e.g. computational load distribution among the processors). The same generally applies to differently implemented logic for implementing the respective functions. It is understood that one or more of the method steps described in detail herein may be performed (e.g. implemented) through one or more specific functions performed by the processor.

The term “regulator” (also referred to as a “controller” or “actuator”) may be understood as a converter configured to influence a state of a process (e.g. a coating process) or a device in response to controlling the regulator. The regulator may convert a signal fed to it into mechanical movements or changes (called controlling) in physical quantities such as pressure, gas flow, or temperature. For example, an electromechanical regulator may be configured to convert electrical energy into mechanical energy (e.g. through movement) in response to controlling.

Controlling a regulator may be done by means of a control signal (e.g. electrical control signal (e.g. an electrical voltage) or fluid-mechanical control signal), which may be applied to a control input of the regulator. The fluid-mechanical control signal may be applied by means of an electrically controllable valve, i.e. which may be controlled by means of the electrical control signal. The generation of the electrical control signal may be performed by means of the control device (e.g. a signal generator thereof). The regulator may, for example, be configured to convert the control signal into an interaction which causes a change of the actual state, e.g. by means of a mechanical force, a magnetic field or the like.

A system (e.g. vacuum arrangement) may include one or more than one vacuum chamber and, in the operational state, a pumping system (including at least one low vacuum pump and optionally at least one high vacuum pump) fluidly coupled to the interior of the vacuum chamber (also referred to as the chamber interior). According to various embodiments, the vacuum chamber may be provided by means of a chamber housing configured to provide a vacuum (i.e., a pressure lower than 0.3 bar) in the chamber interior, e.g., a vacuum atmosphere and/or according to a set pressure. The pump system may be configured to extract a gas from the chamber interior so that the vacuum may be provided therein, for example according to the set pressure.

The term “vacuum” may be understood as including a pressure of less than 0.3 bar, e.g. in a range from about 10 mbar (millibar) to about 1 mbar (in other words low vacuum) or less, e.g. in a range from about 1 mbar to about 10⁻³ mbar (in other words medium vacuum) or less, e.g. in a range from about 10⁻³ mbar to about 10⁻⁷ mbar (in other words high vacuum) or less.

As noted above, the spatial distribution with which the material vapor flow exits from an array of emission nozzles may be subject to disturbances, for example, due to variations in the characteristics of the emission nozzles, flow-related variations in the tube, finite tube length, and the like. According to various embodiments, a method and a steam distribution device (including, for example, a linear evaporator) are discussed in more detail below that may make it easier to counteract these disturbances. In particular, the disclosed method and a steam distribution device may facilitate influencing the coating process while it is taking place, for example, to reduce layer inhomogeneity during the coating process or even to inhibit formation of layer inhomogeneity.

According to various embodiments, the coating process is carried out by means of thermal evaporation and by means of a linear evaporator on a (e.g. large) substrate, in which the linear evaporator includes, for example, one row of nozzles (e.g., exactly one) that helps distribute the evaporation material homogeneously onto the substrate in the form of vapor.

According to various embodiments, reference is made to a so-called vaporizing material (also referred to as coating material or material to be vaporized, e.g. a layer-forming material), which may be brought into various aggregate states, for example from solid (initial state) to gaseous and back to solid (e.g. as a coating). The transition to the gaseous state of aggregation (simplified also referred to as gaseous state or as vapor), the so-called vaporization, may occur directly from the solid state (including a phase transition of a solid to the gaseous state of aggregation) or via the liquid state (including a phase transition of a liquid to the gaseous state of aggregation) of the material to be vaporized. The term “vaporization” as used herein may also include boiling, evaporation and/or sublimation.

The steam distribution device may be part of an evaporation device further including a crucible for evaporating the coating material.

Components of the steam distribution device and/or vaporization device (for example, steam distribution channel, nozzle(s), and/or crucible) that are exposed to and/or heated by the vaporization material may, according to various embodiments, be stable (physically and/or chemically) with respect to the vaporization material, for example, when brought to an operating temperature. The operating temperature may be greater than a temperature (also referred to as a gas transition temperature) at which the vaporization material changes to a gaseous state (also referred to as vaporizing). For example, the operating temperature and/or the gas transition temperature may be greater than about 200° C., e.g., greater than about 400° C., e.g., greater than about 600° C., e.g., greater than about 800° C., etc.

Components of the steam distribution device and/or evaporation device (for example, steam distribution channel, nozzle(s), and/or crucible) may, according to various embodiments, include or consist of a ceramic (e.g., including or consisting of fused silica, alumina, or silicon carbide (SiC)).

A nozzle (also referred to herein as an emission nozzle) refers to a fluid-conducting component penetrated by an opening (also referred to as a nozzle opening or orifice) through which vapor may flow (also referred to as a material vapor flow, more simply as a vapor flow, or more generally as a material flow), e.g., out into free space. The material vapor flow may include vapor (i.e., a gaseous vaporized material) and optionally one or more than one impurity (e.g. a fluid). Examples of the impurity include: another gaseous material, clusters of material, droplets, or the like.

The nozzle opening provides a constriction along the flow path for the material vapor flow, through which constriction the material flow passes. Upstream and/or downstream of the nozzle, the flow path may pass through a cross-sectional area that is larger than the cross-sectional area of the nozzle opening. The nozzle may have the same cross-sectional area along its entire length, widen, taper, or have other complex shapes. The nozzle does not perform any work, but converts between velocity and static pressure of the material flow. By means of a nozzle, the material flow (e.g., including the evaporation material) may be accelerated along a pressure gradient, for example.

According to various embodiments, the vacuum arrangement may include a transport device configured to transport the substrate in and/or through the vacuum chamber (also referred to as “substrate transport process” or “substrate transport” for short), e.g. along a transport path. The transport device may include, for example, a plurality of rollers (or drums) with which the transported substrate comes into contact, or at least one substrate carrier that supports the transported substrate.

In the following, various examples are described that relate to what has been described above and what is shown in the figures.

Example 1 is a method including: coating a substrate (also referred to as coating process) by means of a material vapor flow, which is preferably provided by means of thermal evaporation of an evaporation material and/or emitted from a plurality of emission nozzles; superposing the material vapor flow with a gas flow (e.g. preferably so that a spatial distribution of the material vapor flow and/or a spatial distribution with which the coating takes place is influenced by means of the gas flow, wherein the gas flow (e.g. its spatial distribution) is provided, for example, by means of a regulator which is controlled according to a specification which is optionally stored and/or time-invariant.

Example 2 is a method (e.g., according to example 1), including: determining an information (also referred to as distribution information) (e.g., a data reading) representing a spatial distribution of a material vapor flow emitted from a plurality of emission nozzles; controlling a regulator configured to affect a gas flow (e.g., its spatial distribution) superposed on the material vapor flow based on the information.

Example 3 is the method according to example 2, wherein the information is based on a result of a coating process to which the material vapor flow is fed (e.g., performed by means of the material vapor flow), and preferably based on a coating (as a result of the coating process) and/or its spatial distribution formed by means of the coating process.

Example 4 is the method according to example 2 or 3, wherein the result of the coating process is captured sensorially, preferably while the coating process is performed (e.g. by means of the material vapor flow) and/or while the material vapor flow is supplied to the coating process. For example, result of the coating process may be captured sensorially outside (also referred to as ex-situ) the vacuum (also referred to as the process vacuum) in which the coating process is carried out (e.g. under earth-atmospheric air pressure), or within the process vacuum (also referred to as in-situ).

Example 5 is the method according to any of examples 2 to 4, wherein controlling the regulator is performed according to a first specification based on (e.g. determined based on) the information, the first specification preferably representing a spatial distribution (then also referred to as a target distribution) of the gas flow.

Example 6 is the method according to any of examples 2 to 5, wherein the determining is performed based on a substrate after the substrate has been coated by means of the material vapor flow, for example in-situ (e.g., by spectroscopy) or outside the process vacuum (ex-situ).

Example 7 is the method according to any of examples 2 to 6, wherein the controlling is time-dependent and/or wherein the information is time-dependent.

Example 8 is the method according to any of examples 2 to 7, wherein the information represents a deviation of the spatial distribution of the material vapor flow from a second target (also referred to as target distribution), the controlling being configured to counteract the deviation.

Example 9 is the method according to any of examples 1 to 8, wherein the gas flow is directed towards the material vapor flow and/or influences its spatial distribution (e.g. scattering it or at least partially displacing it). For example, a mixture of constituents (e.g. individual atoms, molecules, or other particles) of the gas flow and the material vapor flow occurs, as a result of which collisions between the constituents occur. The collisions promote scattering of the material vapor flow and thus a change in direction of the material vapor flow. The unaffected spatial distribution of the material vapor flow may, for example, follow Lambert's law and be similar to a Gaussian bell curve or, more precisely, a cosine distribution in which the density of the material decreases from the center of the material vapor flow to the edge of the material vapor flow. The shape of the spatial distribution of the material vapor flow is influenced by the gas flow.

Example 10 is the method according to any of examples 1 to 9, wherein the gas flow includes an inert gas (which is inert to the material vapor flow), e.g., a noble gas.

Example 11 is the method according to any of examples 1 to 10, wherein the material vapor flow includes a material that is solid at standard conditions (e.g., a temperature of 293.15 Kelvin and a pressure of 101 325 Pascals).

Example 12 is the method according to any of examples 1 to 11, wherein the gas flow includes a material that is gaseous at standard conditions (e.g., a temperature of 293.15 Kelvin and a pressure of 101 325 Pascals).

Example 13 is the method according to any of examples 1 to 12, wherein the plurality of emission nozzles are configured to emit the material vapor flow having a first spatial distribution, the gas flow being configured to transform the first spatial distribution into the second spatial distribution (with which, for example, coating is performed), preferably the second spatial distribution having a smaller variation (e.g., of flow rate) and/or a smaller spatial variance (e.g., spatial dispersion and/or spread) than the first spatial distribution.

Example 14 is the method according to any one of examples 1 to 13, wherein the material vapor flow is provided by means of thermal vaporization of a vaporization material.

Example 15 is the process according to example 14, wherein the spatial distribution of the gas flow is invariant when a coating process is carried out by means of the material vapor flow. This illustratively provides that the substrate is coated under time invariant conditions and thus increases the homogeneity of the coating.

Example 16 is a computer program configured to perform the method according to any of examples 2 to 15.

Example 17 is a computer-readable medium storing instructions configured to, when executed by a processor, cause the processor to perform the method according to any of examples 2 to 15.

Example 18 is a control device including one or more than one processor configured to perform the method according to any of examples 2 to 15.

Example 19 is a steam distribution device (e.g., operated by the method of any one of examples 1 to 15), including: a steam distribution channel including a cavity; a plurality of emission nozzles fluidly coupled to one another by the cavity for emitting a material vapor flow out of the cavity (e.g. having a first spatial distribution), a plurality of gas outlets (e.g. directed towards the material vapor flow) for providing a gas flow superposed on the material vapor flow; preferably a regulator configured to influence the gas flow, e.g. its spatial distribution; further preferably the control device according to example 18 configured to control the regulator.

Example 20 is the steam distribution device of example 19, wherein the plurality of emission nozzles are arranged in series along a direction, wherein the plurality of gas outlets are arranged in series along the direction.

Example 21 is the steam distribution device of example 19 or 20, wherein the plurality of gas outlets are directed towards an area to which the material vapor flow is emitted from the cavity.

Example 22 is the steam distribution device according to any of examples 19 to 21, further including: a heating device (which is preferably thermally coupled to and/or surrounds the steam distribution channel) configured to supply thermal energy to the steam distribution channel and/or the plurality of emission nozzles. This may inhibit clogging of the steam distribution device. Preferably, the heating device may be located between at least one (i.e., one or more than one) of the plurality of gas outlets and the steam distribution channel. This may reduce the thermal load on the gas outlets.

Example 23 is the steam distribution device according to any of examples 19 to 22, wherein the plurality of gas outlets are directed toward the material vapor flow.

Example 24 is the steam distribution device according to any one of examples 19 to 23, wherein the steam distribution channel includes a channel housing and a plurality of openings penetrating the channel housing and opening into the cavity; wherein each emission nozzle of the plurality of emission nozzles, includes a nozzle head disposed in an opening of the plurality of openings. This may simplify the design of the steam distribution device.

Example 25 is a vacuum arrangement, including: the steam distribution device according to any of examples 19 to 24, and a vacuum chamber in which the steam distribution device is arranged, wherein preferably a transport device transports a substrate through the vacuum chamber and/or past the steam distribution device.

Example 26 is one of examples 1 to 25, wherein the emission nozzles are arranged as a row in series, for example along a first direction that is, for example, transverse to a second direction in which the substrate is transported (also referred to as the transport direction) and/or is transverse to a third direction in which the material vapor flow is emitted (also referred to as the emission direction).

Example 27 is a method including determining an information representing a spatial distribution of a material vapor flow emitted from a plurality of emission nozzles. The method also includes controlling a regulator configured to affect, based on the information, a gas flow superposed on the material vapor flow.

Example 28 is the method according to example 27, wherein the information is based on a result of a coating process to which the material vapor flow is supplied.

Example 29 is the method according to any of examples 27 to 28, wherein the result of the coating process is captured sensorially while the material vapor flow is supplied to the coating process.

Example 30 is the method according to any of examples 27 to 29, wherein controlling the regulator is performed according to a first specification based on the information, wherein the first specification represents a desired spatial distribution of the gas flow.

Example 31 is the method according to any of examples 27 to 30, wherein the information represents a deviation of the spatial distribution of the material vapor flow from a second specification, wherein the controlling is configured to counteract the deviation.

Example 32 is the method according to any of examples 27 to 31, wherein the determining is based on a substrate after the substrate has been coated using the material vapor flow.

Example 33 is the method according to any of examples 27 to 32, wherein the controlling is time-dependent and/or wherein the information is time-dependent.

Example 34 is the method according to any of examples 27 to 33, wherein the gas flow is directed towards the material vapor flow and/or influences its spatial distribution, preferably scattering it or at least partially displacing it.

Example 35 is a steam distribution device including a steam distribution channel including a cavity, a plurality of emission nozzles fluidly coupled to each other by the cavity for emitting a material vapor flow out of the cavity, and a plurality of gas outlets for providing a gas flow superposed on the material vapor flow.

Example 36 is the steam distribution device according to example 35, wherein the plurality of emission nozzles are arranged in series along a direction, wherein the plurality of gas outlets are arranged in series along the direction.

Example 37 is the steam distribution device according to either of examples 35 or 36, wherein the plurality of gas outlets are directed to an area to which the material vapor flow is emitted from the cavity.

Example 38 is the steam distribution device according to any of examples 35 to 37, the steam device further including a regulator configured to influence, based on a control device, the gas flow, wherein the control device is configured to determine an information representing a spatial distribution of the material vapor flow and control the regulator to influence, based on the information, the gas flow.

Example 39 is the steam distribution device according to example 38, wherein the control device is configured to determine a first specification based on the information, wherein the control device configured to control the regulator includes the control device configured to control the regulator based on the first specification, wherein the first specification represents a target distribution of the gas flow.

Example 40 is the steam distribution device according to either of examples 38 or 39, wherein the information is a time-dependent function, wherein the control device is configured to control the regulator according to the time-dependent function.

Example 41 is the steam distribution device according to any of examples 38 to 40, wherein the information represents a deviation of the spatial distribution of the material vapor flow from a second target distribution, wherein the control device configured to control the regulator includes the control device configured to control the regulator to counteract the deviation.

Example 42 is the steam distribution device according to any of examples 35 to 41, wherein the gas flow includes an inert gas with respect to the material vapor flow.

Example 43 is the steam distribution device according to example 42, wherein the inert gas includes a noble gas.

Example 44 is the steam distribution device according to any of examples 35 to 43, wherein the plurality of emission nozzles are configured to emit the material vapor flow with a first spatial distribution, the gas flow being configured to transform the first spatial distribution into a second spatial distribution.

Example 45 is the steam distribution device according to example 44, wherein the second spatial distribution has a smaller flow rate variation or a smaller spatial variance in spatial dispersion than the first spatial distribution.

Example 46 is a method including coating a substrate using a material vapor flow emitted from a plurality of emission nozzles and superposing the material vapor flow with a gas flow so that a spatial distribution of the material vapor flow is influenced by means of the gas flow.

It may be understood that the information may be determined once for a specific configuration of the plurality of emission nozzles (or the steam distribution device), and the spatial distribution of the gas flow based thereon (also referred to as spatial gas distribution) is maintained as long as the configuration remains unchanged. In this case, the spatial distribution of the gas flow may be adapted to the individual steam distribution device. However, determining the information may also be repeated as needed, for example, if inaccuracies are suspected or if the configuration is suspected of being out of alignment.

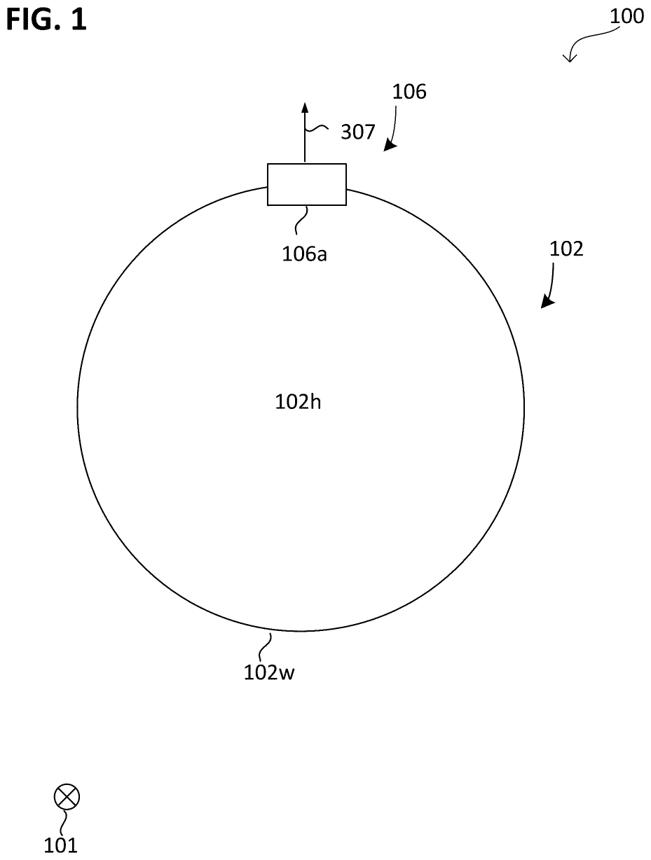

FIG. 1 illustrates a steam distribution device 100 according to various embodiments, e.g., configured and/or operated according to any of examples 1 to 25, in a schematic side view or cross-sectional view, e.g., along direction 101 (also referred to as direction of longitudinal extension or transverse direction 101).

The steam distribution device 100 includes a steam distribution channel 102 (also referred to as a channel-shaped base body 102), for example a tube, including a cavity 102h (also referred to as a steam space 102h). The cavity 102h may extend into (but not necessarily through) the base body 102, e.g., along the transverse direction 101. For example, the cavity 102h may be bounded on at least four sides by a channel housing 102w (e.g., including one or more than one wall) of the base body 102. For example, an extent of the cavity 102h along the transverse direction 101 may be at least 1 meter (m), e.g., 2 m or more, or less than 1 m, e.g., in a range of about 0.2 m to about 1 m (or 0.5 m), e.g., about 0.3 m.

The steam distribution device 100 includes, for example per cavity 102h, a plurality 106 of emission nozzles 106a (more simplify referred to as nozzle) opening into the cavity 102h and configured to emit the vaporized material (out of the cavity 102h) in an emission direction 307. The emission direction 307 emanating from each of these nozzles may, for example, lie on a planar plane which may, for example, be parallel to the direction 101.

In an exemplary implementation, the number of nozzles 106a of the plurality 106 of emission nozzles, e.g., per meter of extent of the cavity 102h along the transverse direction 101, may be 5 or more, e.g., 10 or more, e.g., 20 or more, e.g., 30 or more, e.g., 40 or more, e.g., 50 or more.

The plurality 106 of emission nozzles includes, for example per cavity 102h, one or more than one row of emission nozzles (also referred to as a nozzle row) arranged in series along the transverse direction 101. The plurality 106 of emission nozzles are fluidly coupled to each other by means of the cavity 102h. It may be understood that the plurality 106 of emission nozzles may (but need not) include, for example, a plurality of rows of nozzles arranged side by side, for which the description herein may apply by analogy.

Generally, the fluidly interconnected components of the steam distribution device 100 may include or be formed from a high temperature resistant material and/or include or be formed from the same material. This achieves that steam of a high temperature vaporizing material may be reliably distributed by means of the steam distribution device 100. For example, the high temperature resistant material may include a transformation range (e.g., melting point or glass transition temperature) to a viscous state of greater than about 1000° C., e.g., greater than about 1500° C. Examples of the high temperature resistant material include: a dielectric (e.g., including fused silica), a ceramic (e.g., including an oxide, a nitride, and/or a carbide), a metal (e.g., titanium). The high temperature resistant material may also include a mixture of materials or be formed from a plurality of different materials. Optionally, the high temperature resistant material may be chemically inert, e.g., to oxygen and/or to a vaporized salt, a vaporized perovskite, and/or a vaporized organic.

In one exemplary implementation of method 400, the coating thickness is measured when no gas flow is superposed on the material vapor flow (illustratively, with no gas inlet). Then, iteratively changing the spatial gas distribution and measuring the change in coating thickness in response to iteratively changing the spatial gas distribution is performed. If the layer thickness meets a criterion for a specific spatial gas distribution, this spatial gas distribution may be used statically for all subsequent coating processes. Optionally, a sensory capture of the layer thickness may be performed during the coating process. The gas distribution may be controlled by means of a gas flow controller, whose nominal gas flow may be specified by the control device.

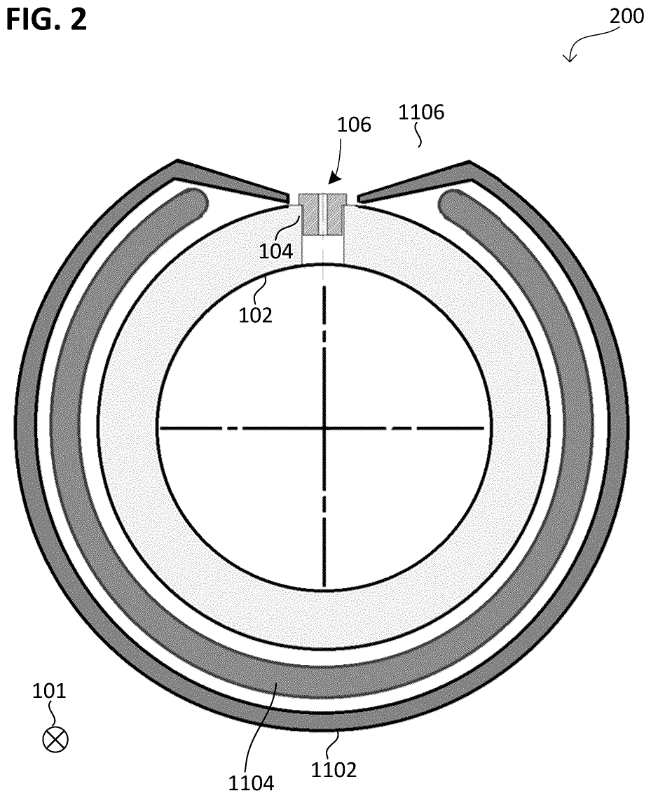

FIG. 2 illustrates a steam distribution device 100 according to various embodiments 200, e.g. configured and/or operated according to any of examples 1 to 25, in a schematic side view or cross-sectional view, wherein the steam distribution device 100 includes a temperature control device 1102, 1104 configured to supply and/or extract thermal energy.

For example, the temperature control device 1102, 1104 may include a heating device 1104 configured to provide thermal energy to the base body 102. The heating device 1104 enables the base body 102 (and/or the crucible) to be brought to a temperature that is above a gas transition temperature of the vaporization material.

Alternatively or additionally, the temperature control device 1102, 1104 may include a cooling device 1102 (e.g., a cooling jacket) configured to extract thermal energy from the gas outlets and/or the environment of the steam distribution device 100 and/or to absorb a portion of the thermal energy emitted by the heating device 1104. This may allow the thermal load to be reduced.

The temperature control device 1102, 1104 may surround the base body 102 and include an opening 1106 (also referred to as a flow-through opening) per nozzle that exposes the nozzle. The flow-through opening 1106 may, for example, overlap with the receiving opening 104 or the nozzle opening. The cooling device 1102 may, for example, include a cavity through which a cooling fluid (e.g., oil or water) may flow during operation. The heating device 1104 may include, for example, a resistive converter (e.g., electrothermal converter) configured to convert electrical energy into thermal energy.

For example, the heating device 1104 may be disposed in a gap between the cooling device 1102 and the base body 102.

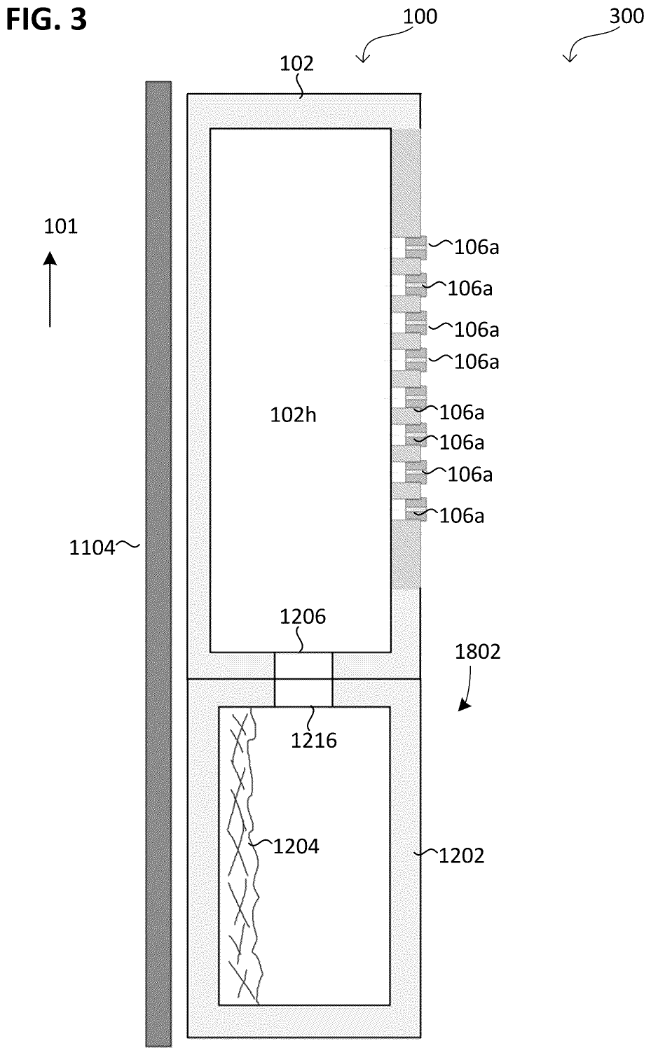

FIG. 3 illustrates an evaporation device 300 (e.g., a linear evaporator) according to various embodiments, e.g., configured and/or operated according to any of examples 1 to 25, in a schematic cross-sectional view (looking in the transverse direction 101). The vaporization device 300 may include a steam distribution device 100, e.g., according to embodiments 100 or 200. The vaporization device 300 may include a steam source 1802 including (e.g., per steam distribution channel 102) one or more than one crucible 1202. Each crucible 1202 may include or be formed from a (e.g., closed or closable) container including an exit opening 1216 (e.g., precisely one). The base body 102 may include an input opening 1206 corresponding thereto that is fluidly coupled to, e.g., adjacent to, the output opening 1216. This coupling (e.g., by means of the output opening 1216 and input opening 1206) may fluidly (e.g., in a gas-conducting manner) connect the interior of the crucible 1202 to the cavity 102h and/or be sealed to the exterior.

In operation, the crucible 1202 may contain an evaporation material 1204 that may be brought to a temperature (also referred to as a gas transition temperature) at which the evaporation material 1204 changes to a gaseous state by applying thermal energy. For example, the gas transition temperature (e.g., sublimation temperature or vaporization temperature) may be greater than about 100° C. (e.g., in a range of about 100° C. to about 150° C.), e.g., more than about 200° C., e.g., more than about 250° C., e.g., more than about 500° C. The application of thermal energy may be accomplished, for example, by means of the heating device 1104.

For example, the evaporation material 1204 may include or be formed from an organic material or may include or be formed from a perovskite material (i.e., a material having a perovskite-type lattice structure).

The methods explained herein may optionally represent exemplary implementations for operating the steam distribution device 100, which are in accordance with embodiments 300 to 200.

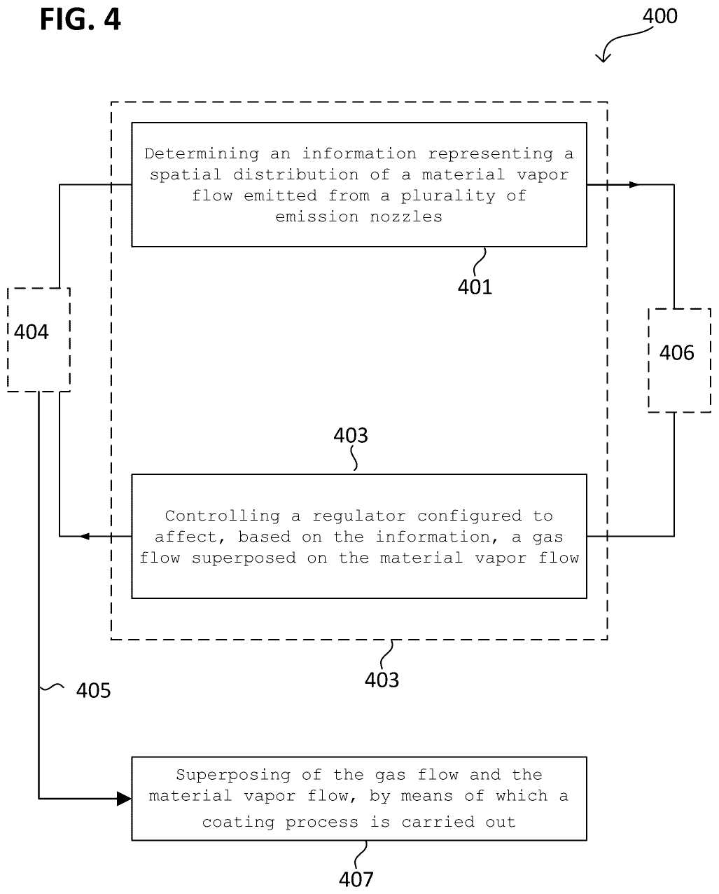

FIG. 4 illustrates a method 400 according to various embodiments, e.g., configured and/or operated according to any of examples 1 to 25, in a schematic flowchart. The method 400 may, for example, be computer-implemented 402, if desired, which facilitates automation. The computer implementation may be, for example, by means of a computer program 402, a computer-readable medium 402, and/or a control device 402. The regulator 404 is configured to influence the gas flow (e.g., its spatial distribution) superposed on the material vapor flow 405, for example, to influence the superposition of the gas flow and the material vapor flow.

Examples of the regulator 404 include: one or more than one gas flow regulator (e.g., mass flow regulator), one or more than one valve (e.g., mixing valve and/or diverting valve), and the like. The diverting valve allows a gas inflow to be divided among a plurality of gas outlets. The gas flow regulator allows to adjust the gas inflow.

In a first exemplary implementation of the regulator 404 (also referred to as a gas regulator), the regulator 404 may be configured to change the gas inflow (e.g., specified as a volumetric flow rate or a mass flow rate) supplied to the plurality of gas outlets. In the first or a second exemplary implementation of the regulator 404, the regulator 404 may be configured to change a distribution of the gas inflow to the plurality of gas outlets. The gas inflow, once adjusted, may be invariant over time during the coating process, for example, or may be changed at a smaller rate (a relative change over time) than the distribution.

Determining the information (also referred to as the emission distribution information) (e.g., a data reading) representing a spatial distribution of a material vapor flow emitted from the plurality of emission nozzles may be performed, for example, by means of at least one sensor 406, e.g., by means of a measurement device including the at least one sensor 406. For example, determining 401 may include translating measurement data from the sensor 406 into the emission distribution information.

In a first exemplary implementation, the spatial distribution of the coating formed by means of the material vapor flow is captured, for example by means of a plurality of sensors. For example, the coating thickness may be captured as the measurand. Then, the or each sensor of the measurement device may be, for example, a layer thickness sensor, for example configured for optical transmission measurement and/or ellipsometry. Alternatively or additionally, an electrical resistor of the coating may be captured as a measurand. Then the measurement device may, for example, include one or more than one resistance sensor.

In a second exemplary implementation, the spatial distribution of the emission rate (e.g., amount per time) and/or the direction with which the material vapor flow is emitted is captured, for example, using a plurality of sensors. For example, the emission rate may be captured as the measurand. Then, the or each sensor may be a rate sensor, for example, configured for rate measurement.

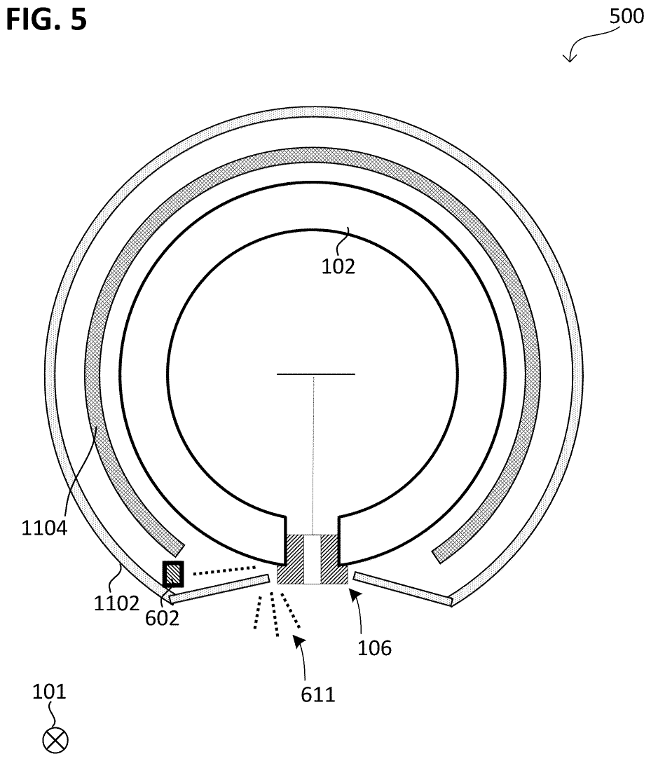

FIG. 5 illustrates a steam distribution device 100 according to various embodiments 500, e.g., configured and/or operated according to any of examples 1 to 25, in a schematic cross-sectional view, looking along the transverse direction 101, in which the plurality of gas outlets include at least one (i.e., one or more than one) gas outlet 602 in an internally mounted configuration (also referred to as internal gas outlet 602) (e.g., per gas control group). Each internal gas outlet 602 may be disposed between the base body 102 and a component of the temperature control device 1102, 1104, e.g., its heating device 1104 and/or cooling device 1102. This internally mounted configuration protects the gas outlet from gaseous coating material (also referred to as vaporization material) flowing out of the plurality 106 of nozzles in the emission direction 307 (also referred to as material vapor flow). This may increase the life of the gas outlet 602.

The gas flow 611 emitted from each internal gas outlet 602 may exit through a gap formed between the base body 102 and the temperature control device 1102, 1104, for example into the flow-through opening 1106 and/or toward the material vapor flow.

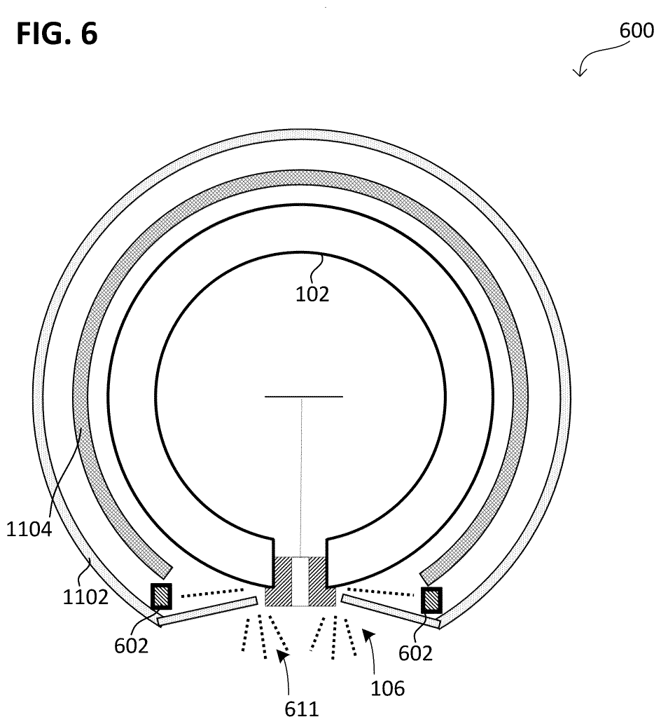

FIG. 6 illustrates a steam distribution device 100 according to various embodiments 600, e.g. configured and/or operated according to any of examples 1 to 25, in a schematic cross-sectional view, looking along the transverse direction 101, in which the plurality of gas outlets includes two internal gas outlets 602 (e.g. per gas actuation group) between which the plurality 106 of nozzles (e.g. row of nozzles) are arranged. This may improve the directionality with which the material vapor flow is affected.

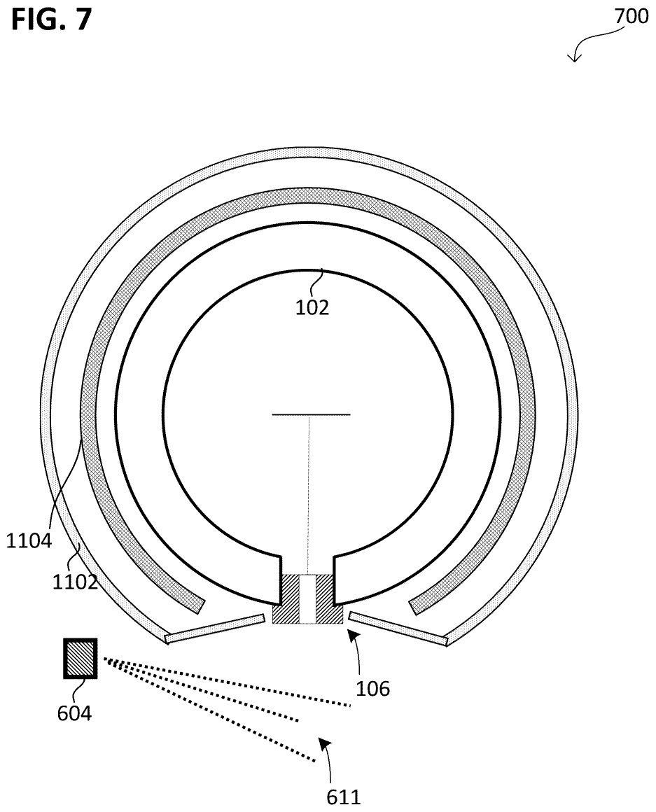

FIG. 7 illustrates a steam distribution device 100 according to various embodiments 700, for example configured and/or operated according to any of examples 1 to 25, in a schematic cross-sectional view, looking along the transverse direction 101, in which the plurality of gas outlets include at least one gas outlet 604 in an externally mounted configuration (then also referred to as external gas outlet 604), for example alternatively or in addition to the at least one internal gas outlet 602.

One or any component of the temperature control device 1102, 1104, for example its heating device 1104 and/or cooling device 1102, may be located between the external gas outlet 604 and the base body 102. This external mounted configuration improves the effect on material vapor flow.

The gas flow 611 emitted from each external gas outlet 602 may be directed past and/or away from the temperature control device 1102, 1104.

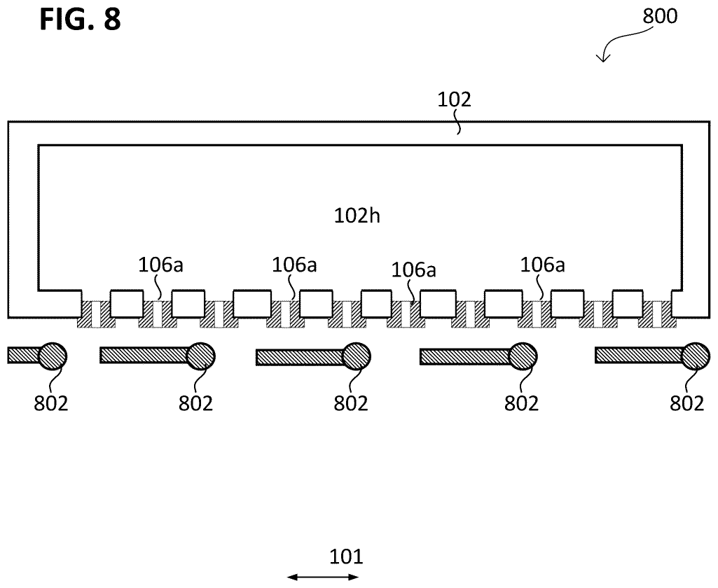

FIG. 8 illustrates a steam distribution device 100 according to various embodiments 800, e.g. configured and/or operated according to any of examples 1 to 25, in a schematic cross- sectional view looking in the transverse direction and/or along the transport direction.

The steam distribution device 100 includes the plurality of gas outlets 802 for providing a gas flow that is superposed on (e.g., directed toward) the material vapor flow. The plurality of gas outlets 802 may include one or more than one internal gas outlet 602 and/or one or more than one external gas outlet 604.

The steam distribution device 100 may include one or more than one gas actuator group. Each gas actuator group includes a regulator 404 (also referred to as a gas actuator) and one or more than one gas outlets 802 coupled to the gas actuator 404 of the gas actuator group by means of a gas line. This may be configured such that by means of driving the gas actuator 404 of the gas actuation group, the gas flow supplied to the one or more than one gas outlets 802 of the gas actuation group may be varied. It may be understood that each gas outlet of the plurality of gas outlets 802 may part of a gas actuation group but this need not necessarily be the case.

The number of gas actuator groups may be selected based on the number of required degrees of freedom in the state space. In a few complex exemplary implementations, the steam distribution device includes at least one gas actuating group including a first gas outlet and a second gas outlet (between which, for example, a plurality of gas outlets are arranged), wherein by controlling the gas actuator 404 the ratio with which the gas inflow is distributed to the first and second gas outlets may be varied. In another exemplary implementation, the steam distribution device includes two gas actuator assemblies that are independently controllable in the flow of gas that they receive and/or dispense. In still another exemplary implementation, the plurality of emission nozzles includes exactly a maximum of one (many degrees of freedom) emission nozzle per gas actuation group, a maximum of two emission nozzles, or a maximum of three emission nozzles. Alternatively or additionally, the number of gas actuator groups, e.g. per meter of its extent of the cavity 102h along the transverse direction 101, may be 2 or more, e.g. 5 or more, e.g. 10 or more, e.g. 20 or more, e.g. 40 or more, e.g. 50 or more.

In an exemplary implementation, a plurality of separately controllable gas inlets 802 are arranged along the steam distribution channel 102 (e.g., a pipe), but outside the material vapor flow (also referred to as the steam flow), through which a small adjustable amount of inert gas (e.g., argon or nitrogen) may be introduced as a gas flow 611.

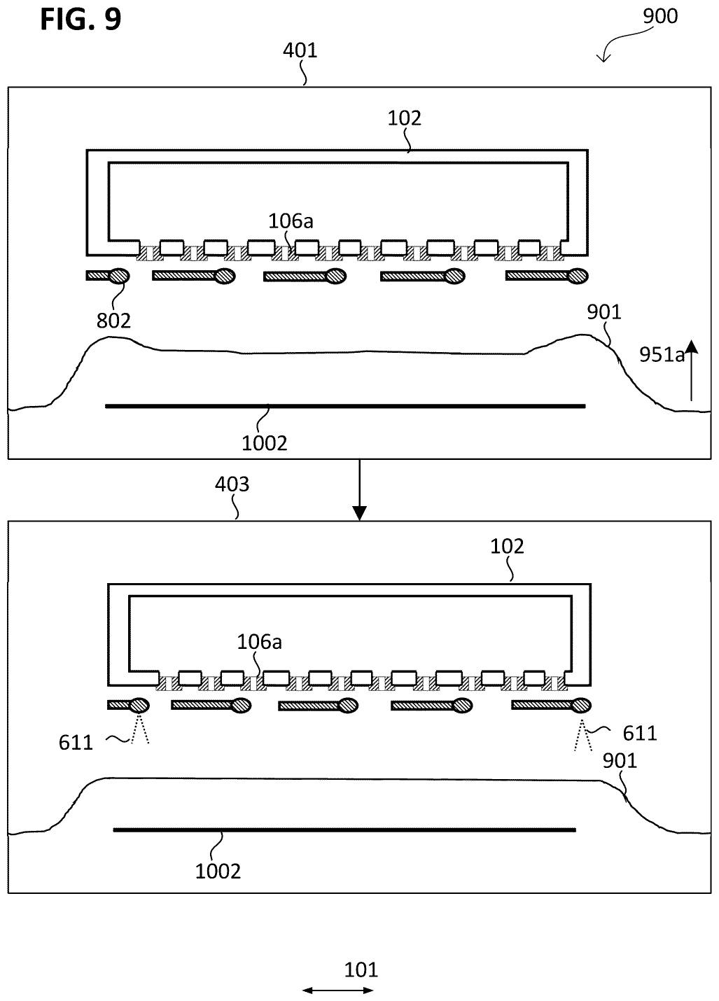

FIG. 9 illustrates the process 400 according to various embodiments 900, e.g., configured and/or operated according to any of examples 1 to 25, in a schematic flow diagram. The method 400 may include transporting a substrate 1002 through the material vapor flow (in the transport direction) and/or coating the substrate using the material vapor flow.

Shown is the spatial distribution 901 (also referred to as material distribution 901) of the amount of material 951a (along the transverse direction 101) deposited on the substrate 1002 (also referred to as coating material distribution 901) as an exemplary distribution information (e.g. a distribution data reading). The spatial distribution 901 of the amount of material corresponds to the spatial distribution of the thickness of a coating formed therewith on the substrate 1002.

In 401, this spatial distribution 901 of the amount of material includes two protrusions on the edges of the substrate 1002.

In 403, a gas flow 611 is superposed on the material vapor flow, which gas flow is discharged from one or more than one gas actuator group. The gas flow 611 is configured to flatten the elevations, or at least reduce the spatial variation of the spatial material distribution 901. In the example shown here, this is achieved by the gas flow 611 including a spatial distribution that also has a maximum at the regions where the material distribution 901 has a local maximum.

In an exemplary implementation, the gas flow 611 (e.g. inert gas) is used to (locally) increase the pressure at locations with “too high” layer thickness, which partially displaces and/or scatters the material vapor flow. Both may reduce the layer thickness locally, whereby the cross-homogeneity may be adjusted specifically by spatial gas distribution.

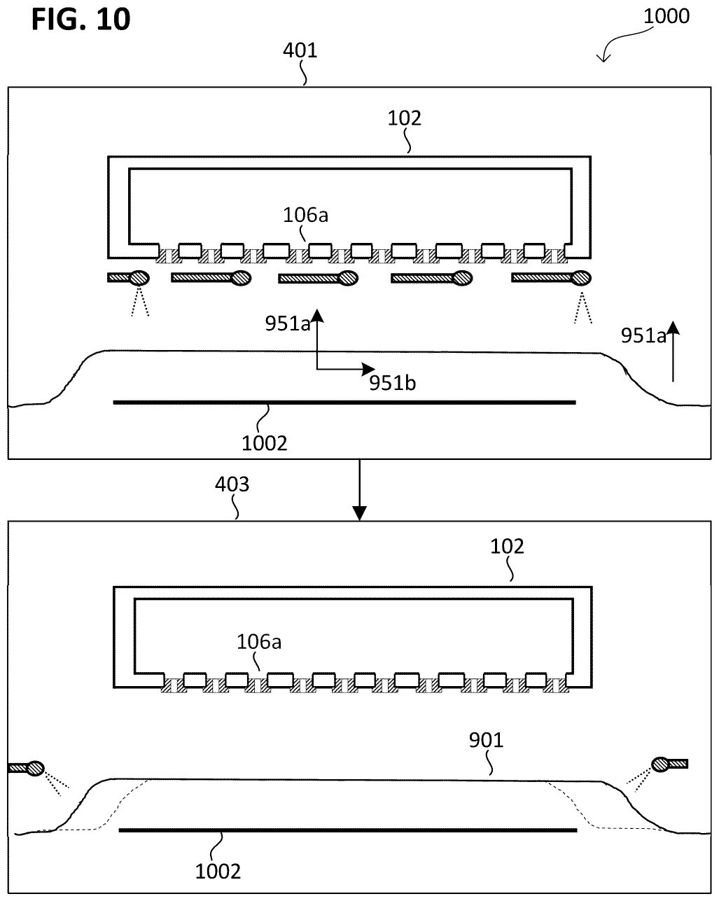

FIG. 10 illustrates the process 400 according to various embodiments 1000, e.g., configured and/or operated according to any of examples 1 to 25, in a schematic flow diagram. The method 400 may include transporting a substrate 1002 through the material vapor flow (in the transport direction) and/or coating the substrate using the material vapor flow.

In 403, a gas flow 611 is superposed on the material vapor flow and is emitted from one or more than one gas actuator group. The gas flow 611 is configured to reduce the amount of material vapor flow emitted past the substrate (e.g., reduce its spatial variance). In the example shown herein, this is accomplished by emitting the gas flow 611 from a face of the base body 102 toward the material vapor flow and/or the substrate 1002.

In an exemplary implementation, two gas outlets 802 are installed on both sides of the substrate 1002 and/or the steam distribution channel 102 on the front side (on the transverse side). By means of the gas flow 611, material that would otherwise arrive next to the substrate 1002 is displaced and/or scattered onto the substrate. This reduces material loss at the edge and increases material efficiency. Optionally, the nozzles 106a may be adjusted at the front of the nozzle array (also referred to as edge nozzles) to reduce the amount of material that reaches the edge region.

While the disclosure has been particularly shown and described with reference to specific aspects, it should be understood by those skilled in the art that various changes in form and detail may be made therein without departing from the spirit and scope of the disclosure as defined by the appended claims. The scope of the disclosure is thus indicated by the appended claims and all changes, which come within the meaning and range of equivalency of the claims, are therefore intended to be embraced.

1. A method comprising:
determining an information representing a spatial distribution of a material vapor flow emitted from a plurality of emission nozzles; and
controlling a regulator configured to affect, based on the information, a gas flow superposed on the material vapor flow.

2. The method according to claim 1, wherein the information is based on a result of a coating process to which the material vapor flow is supplied.

3. The method according to claim 2, wherein the result of the coating process is sensorially captured while the material vapor flow is supplied to the coating process.

4. The method according to claim 1, wherein controlling the regulator is performed according to a first specification based on the information, wherein the first specification represents a desired spatial distribution of the gas flow.

5. The method according to claim 1, wherein the information represents a deviation of the spatial distribution of the material vapor flow from a second specification, wherein the controlling is configured to counteract the deviation.

6. The method according to claim 1, wherein the determining is based on a substrate after the substrate has been coated using the material vapor flow.

7. The method according to claim 1, wherein the controlling is time-dependent and/or wherein the information is time-dependent.

8. The method according to claim 1, wherein the gas flow is directed towards the material vapor flow and/or influences its spatial distribution, preferably scattering it or at least partially displacing it.

9-11. (canceled)

12. A steam distribution device comprising:
a steam distribution channel comprising a cavity;
a plurality of emission nozzles fluidly coupled to each other by the cavity for emitting a material vapor flow out of the cavity; and
a plurality of gas outlets for providing a gas flow superposed on the material vapor flow.

13. The steam distribution device according to claim 12, wherein the plurality of emission nozzles are arranged in series along a direction, wherein the plurality of gas outlets are arranged in series along the direction.

14. The steam distribution device according to claim 12, wherein the plurality of gas outlets are directed to an area to which the material vapor flow is emitted from the cavity.

15. A method comprising:
coating a substrate using a material vapor flow emitted from a plurality of emission nozzles; and
superposing the material vapor flow with a gas flow so that a spatial distribution of the material vapor flow is influenced by means of the gas flow.

16. The steam distribution device according to claim 12, the steam device further comprising a regulator configured to influence, based on a control device, the gas flow, wherein the control device is configured to:
determine an information representing a spatial distribution of the material vapor flow; and
control the regulator to influence, based on the information, the gas flow.

17. The steam distribution device according to claim 16, wherein the control device is configured to determine a first specification based on the information, wherein the control device configured to control the regulator comprises the control device configured to control the regulator based on the first specification, wherein the first specification represents a target distribution of the gas flow.

18. The steam distribution device according to claim 16, wherein the information is a time-dependent function, wherein the control device is configured to control the regulator according to the time-dependent function.

19. The steam distribution device according to claim 16, wherein the information represents a deviation of the spatial distribution of the material vapor flow from a second target distribution, wherein the control device configured to control the regulator comprises the control device configured to control the regulator to counteract the deviation.

20. The steam distribution device according to claim 12, wherein the gas flow comprises an inert gas with respect to the material vapor flow.

21. The steam distribution device according to claim 20, wherein the inert gas comprises a noble gas.

22. The steam distribution device according to claim 12, wherein the plurality of emission nozzles are configured to emit the material vapor flow with a first spatial distribution, the gas flow being configured to transform the first spatial distribution into a second spatial distribution.

23. The steam distribution device according to claim 22, wherein the second spatial distribution has a smaller flow rate variation or a smaller spatial variance in spatial dispersion than the first spatial distribution.
